(19) United States
(12) Patent Application Publication
(10) Pub. No.: US 2007/0290347 A1
(43) Pub. Date: Dec. 20, 2007

(54) SEMICONDUCTIVE DEVICE HAVING RESIST POISON ALUMINUM OXIDE BARRIER AND METHOD OF MANUFACTURE

(75) Inventors: William W. Dostalik, Plano, TX (US); Laura M. Matz, Murphy, TX (US); Robert Kraft, Plano, TX (US); Mark H. Somervell, Richardson, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/425,015

(22) Filed: Jun. 19, 2006

(51) Int. Cl. H01L 21/4763

(52) U.S. Cl. 257/758; 438/622

(57) ABSTRACT

The invention provides a semiconductive device that comprises interlevel dielectric layers that are located over devices. The interlevel dielectric layers have a dielectric constant (k) less than about 4.0. Interconnects are formed within or over the interlevel dielectric layers. The semiconductive device further comprises an aluminum oxide barrier located between at least one pair of the interlevel dielectric layers. The aluminum oxide barrier is substantially laterally co-extensive with the interlevel dielectric layers.

### TECHNICAL FIELD OF THE INVENTION

This invention is directed in general to a semiconductor device and, more specifically, to a semiconductor device having a resist poison aluminum oxide barrier layer and a method of manufacture of that device.

### BACKGROUND OF THE INVENTION

The use of low dielectric constant (low-k) materials in semiconductor devices has gained acceptance in the semiconductor industry. The reason for the use of these materials is that as device sizes have continued to shrink, the interconnect delay times (RC delay) have increased due to increased parasitic capacitance. To combat this increased RC delay, the industry has turned to the use of low-k dielectric materials. However, employing low-k dielectrics requires the use of copper diffusion barriers to the underlying structures, which has been problematic.

To prevent copper diffusion through low-k dieelectrics, the industry places a diffusion barrier, such as a silicon nitride, silicon carbide nitride, or silicon carbide layer between the low-k dielectric layer and the underlying conductive structures. It is typically necessary to perform a chemical pre-treatment to the underlying copper and low-k substrates in order to promote effective adhesion between the copper diffusion barrier and the underlying substrate. For this reason, the industry treats the upper surface of the conductive structures with ammonia prior to forming the copper diffusion layer to enhance adhesion properties.

While the ammonia treatment substantially eliminates the adhesion issues, it introduces photoresist (resist) poisoning issues into the manufacturing process. Resist poisoning refers to the movement of contaminating materials present in various layers that impede or neutralize the effectiveness of the photoactive materials in the photoresist. Since, the low-k materials are very porous, the nitrogen containing amines left behind by the ammonia pre-treatment process can move easily through them. The resist is considered poisoned because the contaminating materials alter the reactive properties of the resist. In the instance of the ammonia treatment, the basic ammines neutralize the acids required to pattern the resist. Resist poisoning, in turn, can affect significant regions of the pattern, resulting in an imperfect transfer of the intended pattern into the substrate. This, in turn, results in missing device circuit features, rendering the integrated circuit (IC) useless.

In addition to the ammonia treatment of the upper surface of the previous level dielectric and conductive structures causing resist poisoning, the deposition process used to form a via etch stop layer located on the conductive structures can also introduce resist poisoning. For example, many via etch stop layers contain nitrogen, the nitrogen typically being introduced with ammonia. Unfortunately, the ammonia that remains within the via etch stop layers after their manufacture, causes similar resist poisoning issues that typically results from the ammonia treatment of the conductive structures.

To combat this problem, some manufacturers have added additional barrier layers or have deposited thick sacrificial dielectric layers to help reduce the effects of resist poisoning. While these techniques have helped, they introduce their own set of processing problems. For example, the added thickness associated with the sacrificial dielectric layers increases the aspect ratio during via formation. This increased aspect ratio can cause the barrier/seed deposition and copper fill processes to be incomplete and results in a via that is not adequately filled. In turn, voids are formed in the via, which can result in a defective interconnect. Additionally, where the barrier layers are left in the structure, they can increase the overall effective dielectric constant of the device due to their higher dielectric constants compared to adjacent interlevel dielectric layers. This can add unwanted parasitic capacitance to the device.

Accordingly, what is needed in the art is a semiconductive device and method of manufacturer thereof that avoids the disadvantages associated with the current devices and processes.

### SUMMARY OF THE INVENTION

The invention provides, in one embodiment, a semiconductive device that comprises interlevel dielectric layers that are located over a device level. The interlevel dielectric layers have a dielectric constant (k) less than about 4.0. Copper interconnects are formed within or over a plurality of the interlevel dielectric layers. The semiconductive device further comprises an aluminum oxide barrier that is located between at least one pair of the interlevel dielectric layers and has a thickness that is less than about 10 nm. The aluminum oxide barrier is also substantially laterally co-extensive with the interlevel dielectric layers.

Another embodiment of the invention provides a method of manufacturing a semiconductor device. This embodiment comprises the steps of forming transistors over a semiconductor substrate, forming organo-silicate glass (OSG) layers over the transistors, where the OSG layers have dielectric constants less than about 4.0, and a resist poisoning agent is located within the semiconductor device. The method further comprises forming interconnects within and over each of the OSG layers, and placing an aluminum oxide barrier between each of the OSG layers. The aluminum oxide barrier provides a resist poison barrier between each of the OSG layers.

In another embodiment, the invention provides a semiconductor device, comprising transistors located over a semiconductor substrate, OSG layers located over the transistors, where each of the OSG layers have a dielectric constant less than about 3.0 and wherein a resist poising agent is located within the semiconductor device. Damascene interconnects are located in the OSG layers and interconnect the transistors, and a barrier layer is located on and is substantially laterally co-extensive with each of the OSG layers. The device further comprises an aluminum oxide (Al₂O₃) barrier that is located on and that is laterally co-extensive with each of the barrier layers. The aluminum oxide barrier has a thickness ranging from about 2.0 nm to about 10 nm.

### BRIEF DESCRIPTION OF THE DRAWINGS

For a more complete understanding of the present invention, reference is now made to the following descriptions taken in conjunction with the accompanying drawings, in which:

FIG. 1 illustrates a partial view of a semiconductive device provided by the invention;

FIGS. 2A-9 illustrate various stages of manufacture of the invention that includes the aluminum oxide barrier;

FIG. 10 illustrates a partial view of a semiconductor device configured as an IC in accordance with the invention.

### DETAILED DESCRIPTION

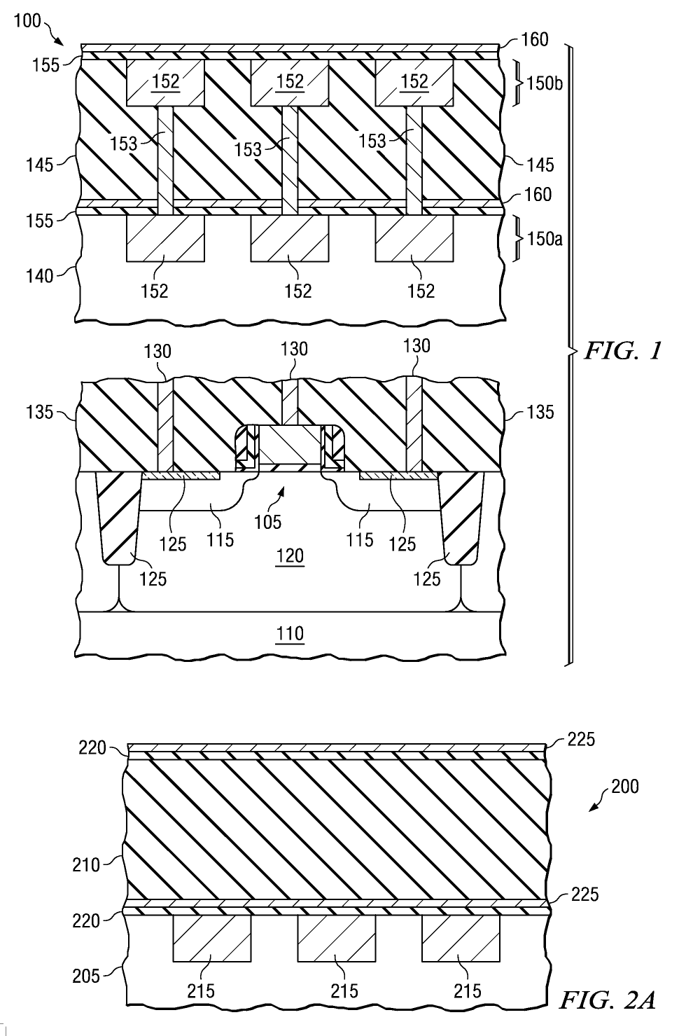

FIG. 1 generally illustrates one embodiment of a semiconductor device 100 of the invention. In this embodiment, the semiconductor device 100 includes a transistor 105 located at a device level and located over semiconductor substrate 110, for example, a semiconductor wafer. The semiconductor substrate 110 may comprise a conventional material, such as silicon, silicon germanium, gallium arsenide, or indium phosphorous. The type and design of the transistor 105 may vary, but in the illustrated embodiment, it is of conventional design. As such, it includes doped source/drains 115 located within a doped well 120. The well 120 may be formed in a separately deposited epitaxial layer, or it may be formed in a portion of the semiconductor substrate 110. The transistor 105 also includes silicided contacts 125 formed in the source/drains 115 to provide a point of contact for contact plugs 130 that are formed in a pre-metal dielectric (PMD) layer 135 that overlies the transistor 105. The PMD layer 135 may be a conventional dielectric material, such as boron phosphorous glass.

The illustrated semiconductor device 100 further includes interlevel dielectric layers (IDL) 140 and 145. IDL 140 and 145 may be deposited as single layers, or they comprise stacked layers. To reduce capacitance, IDL 140 and 145 are comprised of a low-k dielectric material. These low-k materials are often used in dielectric layers past metal level one that is located on the PMD layer 135. The low-k materials typically may be conventional materials that have dielectric constants that are lower than silicon dioxide; that is less than 4.0 and more often 3.0 or in another embodiment about 2.8 or less. When used, low-k materials provide a device that has less parasitic capacitance associated with it, which reduces RC delay. As a result the operating speed of the device is increased. ILD 140 and 145 are representative of any level past metal level one.

Located within each of the ILD 140 and 145 are interconnects 150a 150b, and they may be of conventional design as well. IDL 140 and 145 may contain single damascene interconnects 150a and at least one dual damascene interconnect 150b. IDL 140 and 145 contain metal lines 152 that properly route electrical signals and power properly through the electronic device. IDL 145 also includes vias 153 that properly connect the metal lines of one layer (IDL 145) to the metal lines of another layer (IDL 140). The semiconductor device 100 may also include a conventional barrier layer 155 located on each of ILD 140 and 145. The barrier layer 155 may be a single layer or may comprise a stack of layers. A relatively thin aluminum oxide (AlₓO_{y}) barrier 160 is also included in the semiconductor device 100, and may be a single layer or have a stacked configuration. The advantages of using the AlₓO_{y} barrier 160 by itself or in combination with the barrier layer 155 are discussed below.

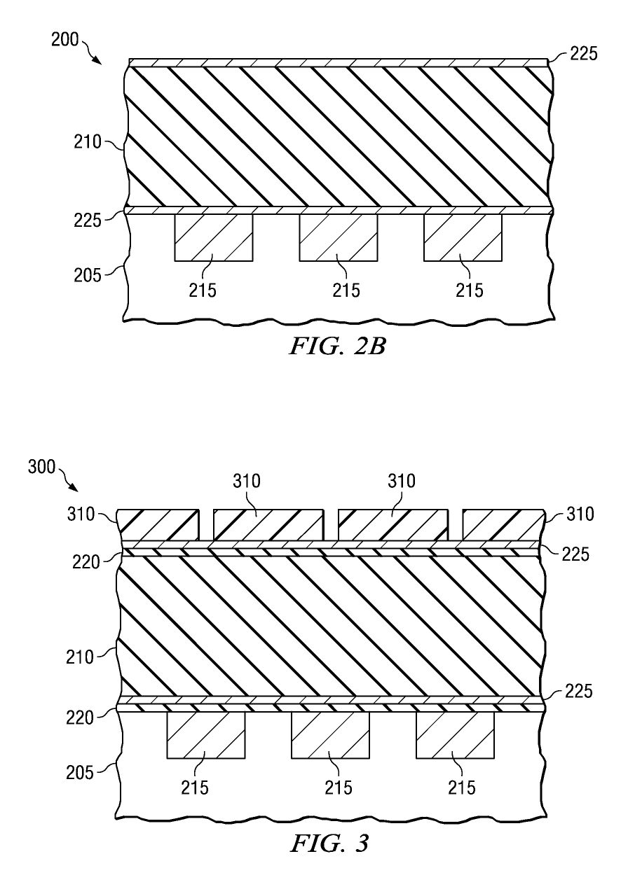

FIG. 2A shows one embodiment of the invention at a stage of manufacturing the interconnects at levels above metal level one. In this embodiment, low-k IDL 205 and 210 are present with previously formed metal lines 215 shown within IDL 205. IDL 205 and 210 are formed over virtually the entire wafer, excluding any outer edges of the wafer that may not be covered by the deposition process (wafer edge effects) . The low-k material may be applied to the substrate with chemical vapor deposition (CVD) processes or a spin-on manufacturing process. An example of the type of low-k material that can be used is OSG, a number of which are commercially available. However, other low-k materials may also be used.

A barrier layer 220 is located on each of the IDL 205 and 210, and as explained below, it may have a number of purposes. The barrier layer 220 may comprise a conventional material, such as silicon, nitrogen, or carbon, and conventional processes, such as plasma enhanced chemical vapor deposition, may be used to deposit this layer to the appropriate thickness. It should be noted that the barrier layer 220 is deposited in a blanket fashion to be substantially laterally co-extensive with the IDLs 205 and 210. That is, the lateral extension of the barrier layer 220 is such that it extends over the entire wafer, excluding any wafer edge effects. The barrier layer 220 may comprise silicon carbide nitride (SiCN), silicon nitride (SiN), silicon carbide (SiC), or combinations thereof. In those instances where the barrier layer 220 contains nitrogen, they often can be poisoning agents in that they can serves as a source for nitrogen that can poison an overlying resist.

Often, low-k IDLs do not adhere well to the metal lines 215. The barrier layer 220 is used to help adhere IDL 205 and 210 to each other. However, the barrier layer 220 often does not adhere well to IDL 205 and 210. To circumvent this problem, the surfaces of IDL 205 and 210 are often treated with ammonia (NH₃) prior to the deposition of the barrier layer 220. A conventional ammonia treatment may be used to treat the upper surfaces of IDL 205 and 210. In addition, the barrier layer 220 may also serve as an etch stop in forming the via of an interconnect.

Following the deposition of the barrier layer 220, in one embodiment, an AlₓO_{y} barrier 225 is deposited over the barrier layer 220. It has been found that the AlₓO_{y} barrier 225 is effective in reducing resist poisoning because it effectively blocks the migration of nitrogen or amines that emanate from the treated IDL or nitrogen that might emanate from the underlying barrier layer 220, both of which may be resist poisoning agents.

The AlₓO_{y} barrier 225 may be deposited using source gases comprising trimethylaluminum (TMA), flowed at rate ranging from about 50 sccm to about 500 sccm, with 250 sccm being used in one advantageous embodiment. Ozone may also be flowed at a rate ranging from about 200 sccm to about 10000 sccm, with 600 sccm being used in one advantageous embodiment, or alternatively, water may be flowed at a rate ranging from about 200 sccm to about 1000 sccm, and at a temperature ranging from about 275° C. to about 350° C. with 300° C. being used in one advantageous embodiment, and at a pressure ranging from about 1 Torr to about 10 Torr, with 3 Torr being used in one advantageous embodiment. The aluminum oxide can be deposited under physical vapor deposition (PVD), atomic layer deposition (ALD) or chemical vapor deposition (CVD) with ALD being used in one advantageous embodiment. These above parameters ensures that the appropriate thickness is obtained because it is highly desirable to control the thickness of the aluminum oxide layer to reduce parasitic capacitance as much as possible.

In one embodiment, the AlₓO_{y} barrier 225 is Al₂O₃. To provide an effective barrier, the AlₓO_{y} barrier is deposited in a blanket fashion such that it is substantially, laterally co-extensive with the IDL over which it is deposited, excluding any wafer edge effects. Though the AlₓO_{y} barrier 225 is laterally co-extensive, it need not be a continuous layer. However, while a non-continuous AlₓO_{y} barrier 225 could provide an effective barrier to resist layer, in an advantageous embodiment, the AlₓO_{y} barrier 225 is a continuous layer.

One advantage in using the AlₓO_{y} barrier 225 of the invention is that a very thin film can be used to reduce resist poisoning as compared to much thicker layers that are presently used. The thickness of the AlₓO_{y} barrier 225 is relatively thin when compared to TEOS layers and barrier layers that are used in previous processes. For example, the thickness of the AlₓO_{y} barrier 225 may be less than about 10 nm and in another embodiment, it may range from about 2.0 nm to about 10 nm. These thicknesses can be as much as one-eighth the thickness of sacrificial TEOS layers or one-quarter the thickness of SiCO barrier layers that are currently used. In place of the AlₓO_{y} barrier 225, previous processes have used sacrificial dielectric layers deposited from tetraethyl orthosilicate (TEOS) gas to reduce resist poisoning in combination with the barrier layer 220. However, the thicknesses required to achieve this could range from 20 nm to 40 nm and to as much as 100 nm or more. These thicknesses increase the aspect ratio, which could result in filling problems as discussed above, and could also increase the overall k_{eff} of the semiconductive device.

With the use of the thinner AlₓO_{y} barrier 225, the aspect ratio of the overall stack is decreased, which reduces the risk of filling problems associated with using thicker layers as in previous processes. In addition, however, it may achieve the same or better k_{eff} as that provided by the thicker TEOS layers. For example, the k_{eff} of the overall dielectric stack containing the thicker TEOS layer may range from about 2.83 to about 2.90, whereas the k_{eff} of the much thinner AlₓO_{y} barrier 225 is less than about 3.0 and may range from about 2.81 to about 2.89 in other embodiments. Thus, an improvement in the k_{eff} can be achieved while using a much thinner material that addresses not only the parasitic capacitance but also the above-mentioned aspect ratio concerns. The use of the AlₓO_{y} barrier 225, however, does not preclude the use of the TEOS layers, particularly in those embodiments where the TEOS layers are sacrificial. Thus, both may be present in certain embodiments.

Another advantage stems from the fact that the AlₓO_{y} barrier 225 has good etch selectivity with respect to the low-k material that comprises IDL 205 and 210. It also has good etch selectivity to the barrier layer 220, which makes it useful as an etch stop or hard mask during the formation of the interconnects. For example, depending on the type of etch chemistry used, the selectivity of the AlₓO_{y} barrier 225 to IDL 205 and 210 may range from about 5 to about 20, and the selectivity of the AlₓO_{y} barrier 225 to the barrier layer 220 may range from about 10 to about 25. This allows the AlₓO_{y} barrier 225 to serve as an etch stop for the via that is formed to make contact with the underlying metal line 215 or serve has a sacrificial hard mask in forming the trench portion of a dual damascene interconnect.

FIG. 2B shows an alternative embodiment. In this embodiment, the barrier layer 220 is omitted and the AlₓO_{y} barrier 225 is deposited on IDL 205 and 210. This configuration illustrates how the AlₓO_{y} barrier 225 can be used as a hard mask in forming interconnect structures, such as damascene or dual damascene structures, in the overlying IDL 210. It also shows how it can be used as an etch stop for making contact with the underlying IDL 205, while at the same time serving has a barrier to resist poisoning.

In FIG. 3 a resist layer 310 has been deposited over the semiconductor device 200 illustrated in FIG. 2A and patterned to form semiconductor device 300. Conventional processes may be used to deposit and pattern the resist layer 310, such as photolithography and plasma ashing processes. The resist layer 310 is patterned to form vias for interconnect structures. In this embodiment, the AlₓO_{y} barrier 225 is located over the IDL 205 and serves as a resist poison barrier to any ammonia emanating from IDL 205. The AlₓO_{y} barrier 225 is also deposited over the IDL 210.

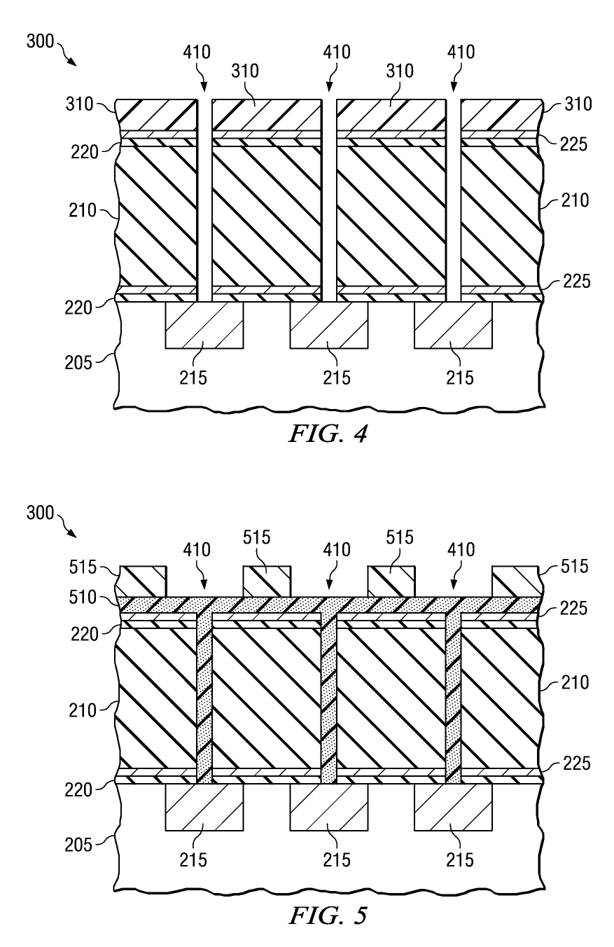

FIG. 4 illustrates the semiconductor device 300 following an etch process that form vias 410 in the IDL 210. A conventional etch, such as one using fluorocarbon etch chemistry, may be used to form vias 410, which may form the via portion of a dual damascene interconnect. Due to the high selectively of the AlₓO_{y} barrier 225, it can serve as an etch stop layer as seen in FIG. 4. In the illustrated embodiment, the via etch is terminated in the AlₓO_{y} barrier 225. This may be the case in those embodiments with and without the underlying barrier layer 220. However, in another embodiment, the etch could be terminated in the barrier layer 220. Since the AlₓO_{y} barrier 225 is present during the deposition and patterning of the resist layer 310, the migration of any ammonia emanating from underlying IDL 205 and 210 is at least significantly reduced when compared to the above-discussed conventional barrier layers. Following the etch, the remaining resist layer 310 is removed and the semiconductor device 300 is cleaned.

In FIG. 5, a bottom anti-reflection coating (BARC) layer 510 may be deposited in the vias 410 and over IDL 210. The BARC layer 510 may be comprised of a conventional organic non-photoactive material that may be applied with a spin-on process. Following this, another resist layer 515 is deposited over the semiconductor device 300 and patterned to form a wider trench pattern for a dual damascene interconnect. The same processes as those used to deposit and pattern resist layer 310 may also be used here.

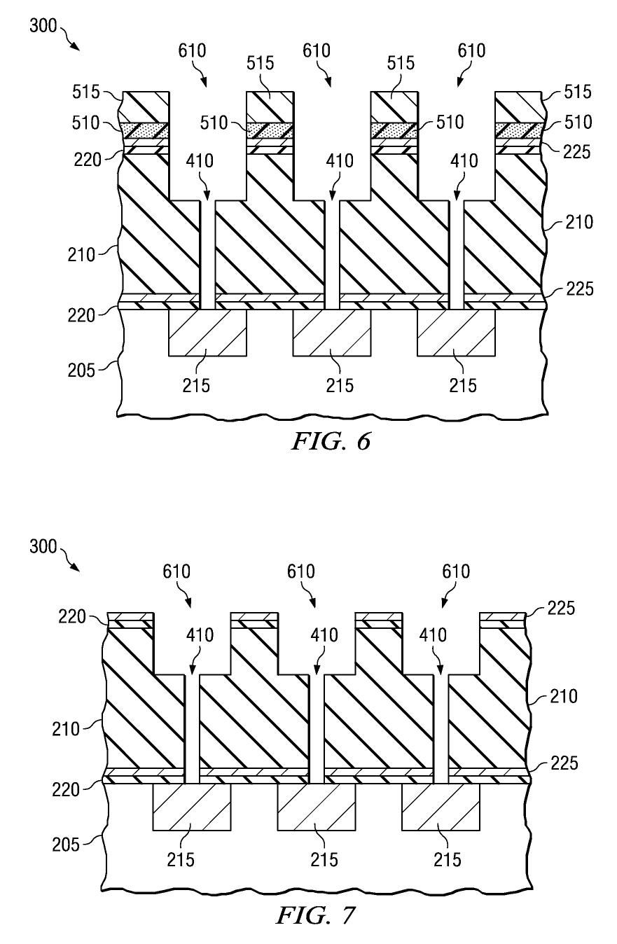

In FIG. 6, an etch is conducted to form trenches 610 of a dual damascene interconnect. The trenches 610 may be etched using any well known manufacturing process, such as fluorocarbon based plasma etches. Due to its good etch selectivity, the AlₓO_{y} barrier 225 located over IDL 210 can function has a hard mask and provides for better etch control and trench formation. If an optional trench stop layer was formed within the IDL 210, then it is used to create the proper trench depth. Otherwise, the trench depth is controlled through manufacturing process techniques known to those skilled in the art. At this point, the etch is conducted to etch through the lower AlₓO_{y} barrier 225 and barrier layer 220 to expose the metal lines 215. Once the trenches 610 have been etched, an ash process removes the remaining portions of the BARC layer 510 and resist layer 515, resulting in the structure shown in FIG. 7.

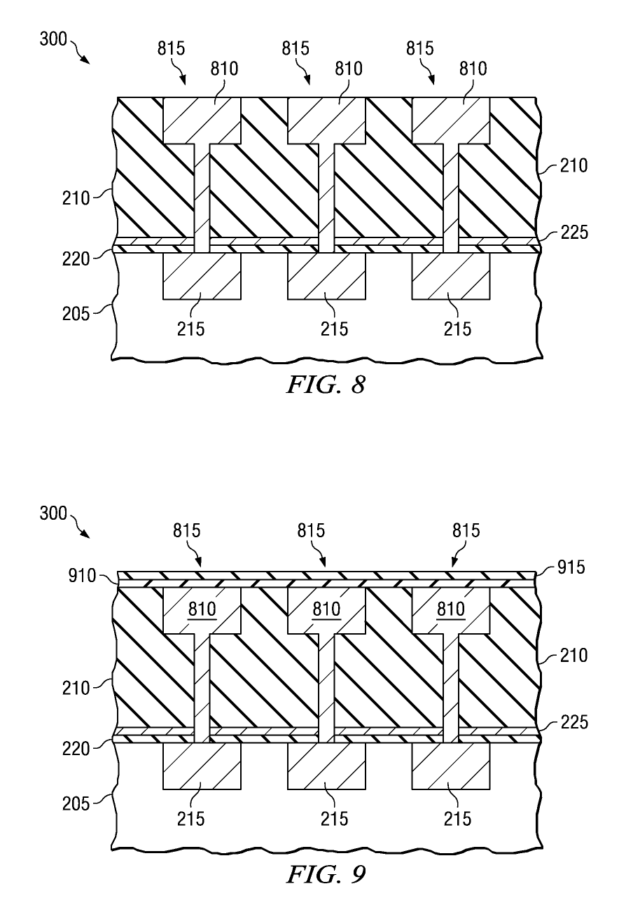

The dual damascene interconnect is completed by filling the trenches 610 and the vias 410 with a metal. Prior to the filling step, conventional metal liners, such as tantalum/tantalum nitride or titanium/titanium nitride liners (not shown), may be formed in the structures. A seed layer may also be then deposited to line the trenches 610 and vias 410. In one embodiment, the metal material may be copper, however, the use of other materials, such as aluminum or titanium, is also within the scope of the invention. Once the trenches 610 and vias 410 are filled with metal 810, the metal is then polished to remove the excess metal and remaining portions of the AlₓO_{y} barrier 225 and barrier layer 220 and expose the top surface of IDL 210, as seen in FIG. 8. This completes the formation of dual damascene interconnects 815 at this metal level.

In FIG. 9, once the dual damascene interconnects 815 are formed, another barrier layer 910 and AlₓO_{y} barrier 915 are formed over interconnects 815 to serve the same function at the next metal level as discussed above. Prior to this, however, the IDL 210 would be treated with ammonia, as discussed above. This process may be repeated at subsequent levels until all of the interconnects are formed. The presence of the AlₓO_{y} barrier at each subsequent level ensures that resist poisoning from one level to the next is reduced. As with previous metal levels, the AlₓO_{y} barrier 915 may be used with or without the barrier layer 910.

From the foregoing it is clear that the invention provides several advantages over conventional processes and devices. As the industry moves forward with copper interconnect structures, such as those found in damascene and dual damascene designs, it is highly desirable to make certain that parasitic capacitance is reduced as much as possible. To that end, the semiconductor industry will continue to use low-k, but highly porous, dielectric materials. However, with their use, resist poisoning will continue to occur when either the dielectric layers are treated with nitrogen or when a nitrogen-containing layer is located within the structure. Thus, the use of thin aluminum oxide barriers located between the dielectric layers will be very useful. They effectively inhibit the diffusion of nitrogen and thereby reduce the amount of nitrogen that reaches the resist. This, in turn, reduces the amount of resist poisoning. As a result, the effective product yields will remain high. Further, because a very thin layer can be used, the parasitic capacitance will be keep within acceptable levels.

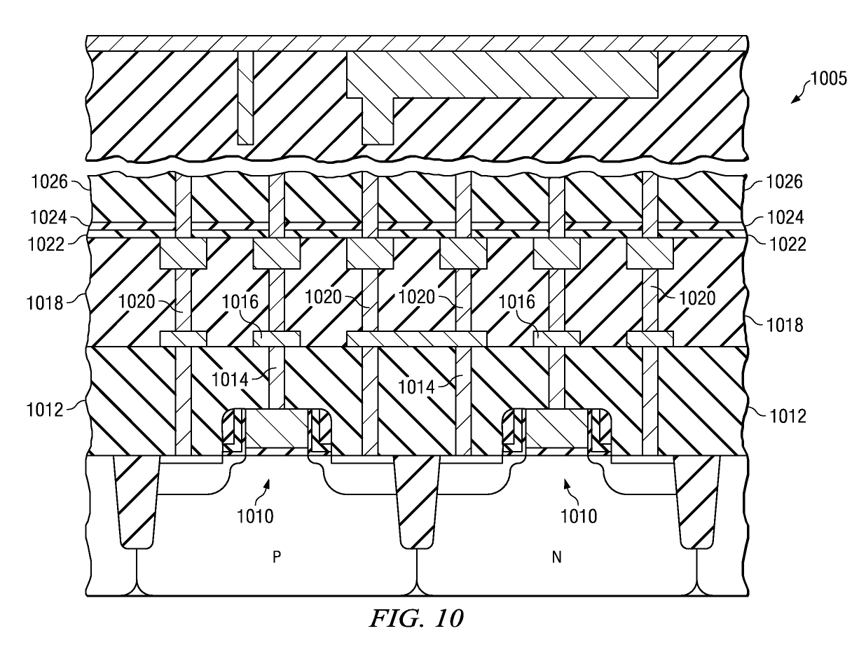

FIG. 10 is representative of one embodiment of the semiconductor device 100 of FIG. 1 can be configured as an IC 1005. This embodiment includes transistors 1010 and the other base structures that comprise the transistors 1010, as discussed above with respect to FIG. 1. A PMD dielectric layer 1012 is located over the transistors 1010 and has contact plug interconnects 1014 formed therein. A first metal level 1016 is located over the PMD layer 1012. Located over the first metal level 1016 is a low-k dielectric material layer 1018 in which are formed dual damascene interconnects 1020, as discussed above. A barrier layer 1022 and AlₓO_{y} barrier 1024, also as discussed above are located over the low-k layer 1018. The IC 1010 includes subsequent low-k layers 1026 and interconnects structures to complete an operative IC. The invention is applicable to many semiconductor technologies, such as BiCMOS, bipolar, silicon on insulator, strained silicon, opto-electronic devices, and microelectrical mechanical systems.

Those skilled in the art to which the invention relates will appreciate that other and further additions, deletions, substitutions and modifications may be made to the described embodiments without departing from the scope of the invention.

What is claimed is:

1. A semiconductive device, comprising:
interlevel dielectric layers located over a device level, wherein the interlevel dielectric layers have a dielectric constant less than about 4.0;
a copper interconnect located over or within a plurality of the interlevel dielectric layers; and
an aluminum oxide barrier located between the interlevel dielectric layers having a thickness that is about 10 nm or less and being substantially laterally co-extensive with the interlevel dielectric layers.

2. The device recited in claim 1, wherein the interconnects include dual damascene interconnects and the aluminum oxide barrier is located on a barrier layer.

3. The device recited in claim 2, wherein the barrier layer comprises silicon, nitrogen, or carbon.

4. The device recited in claim 1, wherein the aluminum oxide barrier is an etch stop layer located on at least one of the interlevel dielectric layers.

5. The device recited in claim 1, wherein the aluminum oxide barrier is Al₂O₃.

6. The device recited in claim 1, wherein the aluminum oxide barrier has a thickness ranging from about 2.0 nm to about 10 nm.

7. The device recited in claim 6, wherein the aluminum oxide barrier has an effective dielectric constant (k_{eff}) is less than about 3.0.

8. A method of manufacturing a semiconductor device, comprising:
forming transistors over a semiconductor substrate;
forming organo-silicate glass (OSG) layers over the transistors, the OSG layers having a dielectric constant less than about 4.0;
a photoresist poisoning agent being present within the semiconductor device;
forming interconnects within each of the OSG layers; and
placing an aluminum oxide barrier between each of the OSG layers to a thickness that is 10 nm or less, the aluminum oxide barrier providing a photoresist poison barrier between each of the OSG layers.

9. The method recited in claim 8, wherein forming the interconnects comprises using the aluminum oxide barrier as an etch stop to form dual damascene interconnects.

10. The method recited in claim 8, further comprising forming etch stop layers between each of the OSG dielectric layers wherein the etch stop layers comprise silicon nitride or silicon carbide.

11. The method recited in claim 8, further including depositing the aluminum oxide barrier on top of one of the OSG dielectric layers and using the aluminum oxide barrier has a hard mask to form the interconnect.

12. The method recited in claim 8, wherein the aluminum oxide barrier is Al₂O₃.

13. The method recited in claim 8, wherein the aluminum oxide barrier has an effective dielectric constant (k_{eff}) is less than about 3.0.

14. The method recited in claim 13, wherein the aluminum oxide barrier has a thickness ranging from about 2.0 nm to about 10 nm.

15. A semiconductor device, comprising:
transistors located over a semiconductor substrate;
organo-silicate glass (OSG) layers located over the transistors, wherein the OSG layers have a dielectric constant less than about 3.0 and a photoresist poisoning agent is located within the semiconductor device.
damascene interconnects formed in the OSG layers that interconnect the transistors;
a barrier layer located on and being substantially laterally co-extensive with each of the OSG layers; and
an aluminum oxide (Al₂O₃) barrier located on each of the barrier layers, the aluminum oxide barrier having a thickness ranging from about 2.0 nm to about 10 nm, and being substantially laterally co-extensive with the barrier layers.

16. The device recited in claim 15, wherein the damascene interconnects include dual damascene structures.

17. The device recited in claim 15, wherein the barrier layers comprise silicon, nitrogen or carbon.

18. The device recited in claim 15, wherein the aluminum oxide barrier has and effective dielectric constants (k_{eff}) that is less than about 3.0.
